(19) United States
(12) Patent Application Publication
(10) Pub. No.: US 2004/0104410 A1
(43) Pub. Date: Jun. 3, 2004

(54) Semiconductor quantum cryptographic device and method

(76) Inventors: Matthew J. Gilbert, Scottsdale, AZ (US); David K. Ferry, Chandler, AZ (US)

Correspondence Address: GALLAGHER & KENNEDY, P. A., 2575 E. CAMELBACK RD. #1100, PHOENIX, AZ, 85016, US

(21) Appl. No.: 10/634,520

(22) Filed: Aug. 4, 2003

Related U.S. Application Data
(60) Provisional application No. 60/400,969, filed on Aug. 2, 2002.

(51) Int. Cl. H01L 27/10

(52) U.S. Cl. 257/202

(57) ABSTRACT

One of two input bias states to a qubit semiconductor waveguide gate controls the transmission of charge carriers to the output of one of two parallel waveguides. Intermediate the ends of the waveguides is a coupling. It permits charge carriers introduced at the input of one of the waveguides to either pass directly along that waveguide to an output end thereof or to move to the other waveguide to be received at that waveguide's output end as determined by an electrical or magnetic bias applied to the device. Acting thus, the gate can be used as a gate in quantum computation. For purposes of encryption, spin polarization of the carriers is controlled. The carriers (electrons, for example) can be in polarized to a single up or down spin condition at a quantum point contact by application of a magnetic field or they can be left unpolarized. The alternative appearance of the carriers at the first or second waveguide output and the spin polarization or lack thereof afford two binary nonorthogonal characteristics of a digital communication under the control of the sender. This permits known cryptographic techniques to be applied to develop an encryption key and encrypt communications between sender and receiver. Attempted decryption by any unauthorized person will be apparent. In an exemplary embodiment the first waveguide is of a uniform width, 35 nm, the second waveguide increases in width, from 25 nm at the input side of the gate to 45 nm at the output side of the coupling. The coupling, a tunneling region, is 335 nm in length.

### RELATED APPLICATIONS

This application claims priority from provisional U.S. patent application serial No. 60/400,969, filed Aug. 2, 2002, entitled Semiconductor Quantum Cryptographic Device and Method, in the names of Matthew J. Gilbert and David K. Ferry. That application is incorporated herein by reference.

This application is related to Patent Cooperation Treaty (PCT) application filed on behalf of the Arizona Board of Regents, as applicant, having the same title as this application, filed concurrently herewith and claiming priority from the same, above-identified U.S. provisional application.

### STATEMENT OF GOVERNMENT FUNDING

Financial assistance for this project was provided by the U.S. Government through the Office of Naval Research under Grant Number N00014-01-1-0741/SC No. 10-6387-1 and the United States Government may own certain rights to this invention.

### FIELD OF THE INVENTION

This invention relates to quantum gate devices useful for quantum computing and in encrypting of quantum computer generated messages.

### BACKGROUND

Recently, quantum computing has received a great deal of focus as a means for replacing the traditional complementary metal-oxide-semiconductor architecture. This has been, in large part, due to the numerous attractive features that quantum computing offers. Of these features, the most popular is the ability to achieve very rapid computation speeds as compared with that of the classical computation. However, in addition to simply being a method to speed the computation, quantum computing offers tremendous promise in areas that are classically unrealizable or impractical, such as quantum teleportation and the factorization of very large numbers into requisite primes. If realized, the latter ability, which exploits the massive parallelism of quantum computation, would render all of the current public codes vulnerable to eavesdropping.

Quantum computation theory has been structured around the use of a qubit, or quantum bit. Two or more bits of quantum information are coupled together to achieve basic logic structures whereby the most basic and essential coupling of two qubits is the controlled not gate (CNOT). One popular realization of this gate is in the Fredkin Gate. E. Fredkin and T. Toffoli, 21 Int. J. Theor. Phys. 219 (1982). The Fredkin gate consists of a control bit, coupled to a qubit, and it operates on the following principle: if a “1” is present in the control bit, then the qubit is passed unchanged. On the other hand, if a “0” is present in the control bit, then the qubit is inverted.

There have been several implementations offered to solve the problem of quantum hacking, but the majority of these implementations have either revolved around the use of differing polarizations of photons or used nuclear magnetic resonance to transmit bits based on different quantum keys, or protocols. The ability to implement a cryptographical system in a solid-state setting has not been offered previously. The ability to encrypt transmissions in a semiconductor setting would enable the cryptography scheme to be integrated into existing semiconductor chips to provide secure transmissions of data.

### BRIEF SUMMARY

In a first aspect of the invention a quantum semiconductor gate is provided. Turning on and off a bias causes the gate output to appear at one or another of the gate outputs. The gate has a pair of waveguides. An input section of at least one of the waveguides leads to a coupling region, where, by tunneling, the two waveguides are coupled. An output section of each of the waveguides leads from the coupling section to an output end of the waveguide. The length of the coupling ordinarily will determine at which of the two waveguide outputs charge carriers (typically electron) moving into the coupling will appear. A biasing element, if activated, causes carriers moving through the input section of the one waveguide into the coupling region to be coupled to the output section of one or the other of the waveguides. An on and off condition of the bias, then, can be considered an input “1” and “0” respectively. At the waveguide outputs, presence of current carrier density can be considered a “1” or high condition and absence of carrier density can be considered a “0” or low condition. Without more, this device can serve as a logic gate for quantum computing.

The biasing element that directs the current carrier density to either the first or the second waveguide output can be either an electrical bias applied across the device or a magnetic bias applied thereto.

The gate can be implemented in a GaAs/AlGaAs heterostructure, although for the cryptographic application described below, an InGaAs/InAs heterostructure is preferred.

Semiconductor device fabrication techniques are used to provide the pair of generally parallel electron waveguides. These are separated at their ends by potentials applied to the semiconductor in which the carriers move by a pair of deposited conductor metal members, called variously gates or barriers. The gates and further metal deposits formed along the device in the direction of wave propagation provide the potentials that bound the waveguides. The deposited metal elements are electrically biased to present the potential barriers. One of the waveguides is of uniform width, i.e. has the same width at both of its ends. The other waveguide is wider at the output side of the device. The two metallic members project toward each other from the input and output ends of the device. The potential barriers that they produce are separated by a tunnel region that forms a coupling where the two waveguides are coupled at their middles so as to permit controlled charge carrier density relocation from one waveguide to the other.

Influencing a flow of electrons by application of a magnetic field to control electron density location in a pair of waveguides coupled at a slot that communicates between them has been reported. J. Harris, R. Akis and D. K. Ferry, Magnetically switched quantum waveguide qubit, 79 App. Phy. Lett. 2214 (2001), incorporated herein by reference. In M. J. Gilbert, R. Akis and D. K. Ferry, Dual computational basis qubit in semiconductor heterostructures, 83 App. Phys. Lett. 1, (2003), incorporated herein by reference, the inventors report simulation of the device of this invention for the purpose of secure encryption.

The inventors have shown that, as here, two waveguides coupled centrally at a tunnel region can be controlled by application of an electrical bias as well as by a magnetic field to effect electron density transfer from one waveguide to the other. M. J. Gilbert, R. Akis and D. K. Ferry, Magnetically and electrically tunable semiconductor quantum waveguide inverter, 81 App. Phys. Lett. 4284 (2003), incorporated herein by reference.

The dimensions contemplated are very small, but are susceptible of scaling up. The first waveguide is about 35 nm wide, the coupling region is 300 to 450 nm long, preferably 335 nm. The input region of the second waveguide is narrow, about 20 nm wide and the output region is wide, about 45 nm wide to assure coupling of the electron density under influence of the bias and without decay.

Built onto the conceptual basis of the gate just described, a semiconductor device or qubit possessing two separate computational bases is provided as a means of circumventing the problem of quantum hacking. The device accomplishes bit encoding both through the control of the location of charge carrier (electron) density and by manipulation of the spin of those charge carriers. This is implemented, in a preferred, exemplary embodiment in an InGaAs/InAs heterostructure that uses a coupled electron wave guide structure with an imbedded quantum point contact. A magnetic or electrical bias is controlled to encode the location of electron density and the application of a magnetic field at the location of a quantum point contact is controlled to manipulate electron spin. The control of electron density location and spin affords two controllable, nonorthogonal features that can be communicated. This enables the implementation of known cryptography techniques to provide bit encoding that is secure against eavesdropping. C. H. Bennett, Quantum cryptography using any two nonorthogonal states, 68 Phys. Rev. Lett. 3121 (1992), incorporated herein by reference, and C. H. Bennet and G. Brassard, Proceedings of IEEE Int. Conf. on Computer Systems, and Signal Processing, Bangalore, India (IEEE, New York, 1984), p. 178, incorporated herein by reference.

Use of a quantum point contact in the presence of a magnetic field to filter electron spin has been shown. See, e.g. M. J. Gilbert and J. P. Bird, Application of split-gate structures as tunable spin filters, 77 App. Phys. Lett. 1050 (2000), incorporated herein by reference. Here, in a quantum gate device of the kind described above, the quantum point contact is used in this manner to filter (i.e. polarize) the spin of electrons moving in a first of the waveguides by Zeeman splitting. Application and removal of the magnetic field toggles the electron current in the waveguide between spin polarized and nonpolarized.

In the preferred embodiment described here, the charge carriers are electrons. It is nevertheless conceivable that the apparatus and method of the invention can employ charge carriers other than electrons, ions for example, that are susceptible to having the spin state of their electrons polarized. Also as described with respect to the exemplary preferred embodiment, application of the electrical or magnetic bias that controls the location of the carrier current at the device's output causes the carrier current to switch from a first waveguide to the output section of a second waveguide. However, it is the length of the coupling tunnel region that determines which waveguide's output section will ordinarily receive the carrier density. So, clearly, the electrical or magnetic bias can be applied to cause the carrier density to appear at the output of the originating waveguide where the coupling length is such as to ordinarily result in the carrier density appearing at the output of the second waveguide rather than the originating waveguide output.

The above and further objects and advantages of the invention will be better understood from the following detailed description of at least one preferred embodiment of the invention, taken in consideration with the accompanying drawings.

### BRIEF DESCRIPTION OF THE DRAWINGS

FIG. 1 is a schematic, functional block diagram and shows an exemplary connection of a device of the present invention with sources of electron flow, bias voltages and magnetic field-producing currents;

FIG. 2 is a diagrammatic illustration, not to scale, showing the dimensions of the device of FIG. 1;

FIG. 3 is a plot of the potential barriers at boundaries of waveguides of the device of FIGS. 1 and 2;

FIG. 4 is a pair of graphs plotting (a) the individual transmissions (T11 and T12) plotted over the coupling length between the two waveguides of the device of FIGS. 1 and 2, and (b) total transmission and reflection plotted over the coupling length between the two waveguides;

FIG. 5 is a series of graphs of (a) density at zero magnetic field with the coupling length f of FIG. 2 set to 335 nm, (b) density with a 0.705T magnetic field applied to the structure of the device of FIGS. 1 and 2, (c) transmissions T12 and T11 plotted over a varying magnetic field, and (d) the total transmission and reflection plotted over a varying magnetic field;

FIG. 6 is a series of graphs of (a) density with zero applied bias at a 335 nm coupling length, (b) density with 0.73 meV applied bias, (c) density with 0.94 meV applied bias, and (d) individual currents (I11 and I12) plotted against a varying applied bias of 0-2 meV;

FIG. 7 is a two dimension depiction of the structure of the device of the invention;

FIG. 8 is a series of graphical representations of the effects of electrical bias on the device of FIGS. 1-3 and 8, (a) showing electron density distribution at a first bias, (b) showing density distribution at a second bias, (c) plotting currents against varying electrical bias, and (d) plotting total current against varying bias;

FIG. 9 is a series of plots of operation of the spin polarizing features of the invention including (a) showing probability varying with energy and magnetic field, (b) showing current varying with energy and magnetic field, (c) plotting current vs. time, and (d) magnetic field vs. time; and

FIG. 10 is a series of plots of vs. time of (a) variable a controlling output location, (b) random variable b controlling spin polarization, (c) current flowing to the output of the input waveguide (I11), and (d) current to the output of output waveguide (I12).

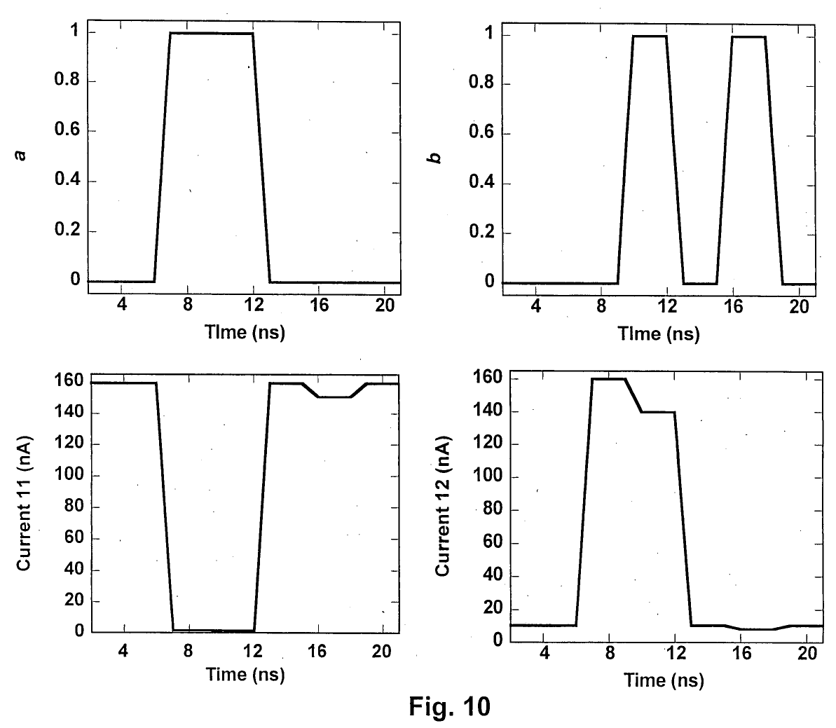

### DETAILED DESCRIPTION

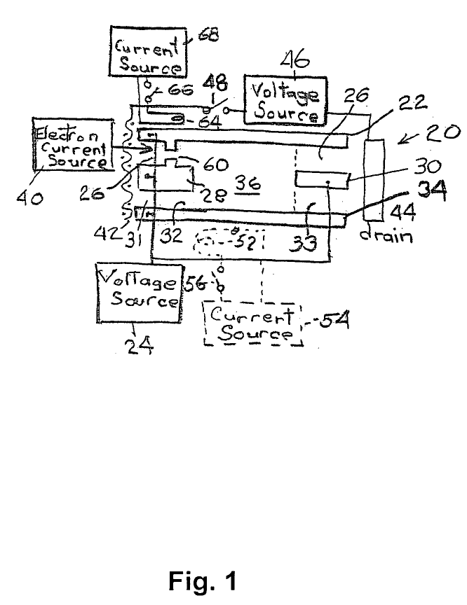

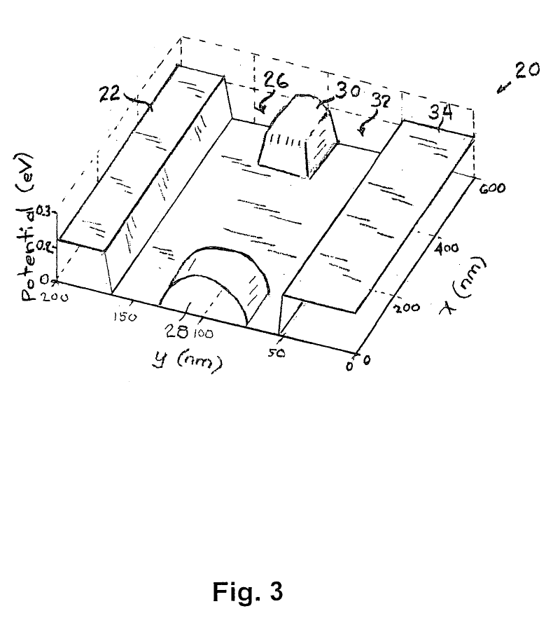

As shown in FIG. 1, a semiconductor logic component 20 has a deposited metal strip 22 that has a potential established by a suitable source of potential shown in FIG. 1 as the voltage source 24. By the potential boundary that it produces in the semiconductor on which it is deposited, the conductive metal strip 22 forms a first, continuous boundary of a first, “input” waveguide 26. A conductive metal member 28 similarly forms a second boundary of the waveguide 26 at the left, input end of the device 20. Again a suitable potential is applied to the member or gate 28 by the voltage source 24. At its further, output end, the waveguide 26 is bounded by the potential afforded by another deposited conductive metal member 30. To this end, this gate 30 is, again, provided a potential as schematically indicated by its connection to the voltage source 24. The waveguide 26 is of uniform width. FIG. 3 plots the potential barriers formed at the metallic strips 22 and 34 and at the two metal members 28 and 30. In the exemplary embodiment described, each potential boundary is slightly greater than 0.2 eV.

The potentials from the members 28 and 30 stand as barriers that isolate the input waveguide 26 from a further, output waveguide 32. The waveguide 32 is bound by the potentials from the two members 28 and 30 and from a further deposited conductive metal strip 34. A potential is applied to the metal strip 34 as indicated schematically by its connection to the voltage source 24. The second, output waveguide 32 is narrower at its left, input end 31 and wider at its right, output end 33 by virtue of the member 30 being narrower than the member 28. The output end of the waveguide 32 is, in fact, wider than the first, input waveguide 26.

Intermediate the potential boundaries of the two gates 28 and 30 lies a tunnel region 36. This tunnel region 36 serves as a coupling between the two waveguides 26 and 32. However, without some biasing influence, in this particular exemplary embodiment, electrons (the charge carriers) introduced at the input end of the first, input waveguide 26 will move through that waveguide to its output end.

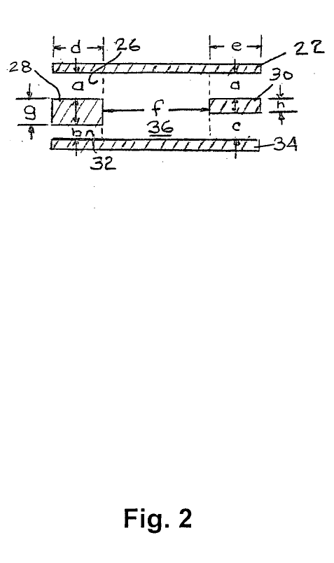

Turning to FIG. 2, the actual dimensions of a preferred, exemplary embodiment of the logic device are as follows:

| | | |
|---|---|---|
| width a of waveguide 26 | 35 | nm |
| width b of waveguide 32 at its input end | 25 | nm |
| width c of waveguide 32 at its output end | 45 | nm |
| length d of the gate 28 | 100 to 150 | nm |
| length e of the gate 30 | 100 to 150 | nm |
| length f of the tunnel region 36 | 335 | nm |
| width g of the gate 28 | 50 | nm |
| width h of the gate 30 | 25 | nm |

Returning to FIG. 1, a source of electron flow 40 introduces electrons into (or causes carrier flow within) the input end of the input waveguide 26. Electrons move toward the tunnel region 36. There is provided a controlled source of bias. This may be electrical. Schematically, for purposes of explanation, a biasing element shown as a potential bearing screen allowing electrons to pass, while presenting a biasing potential with a plate or drain 44, connected to the voltage source 46 through a switch 48. Alternatively, as discussed further below, the bias may be magnetic, as schematically indicated in broken lines in FIG. 1 as the coil 52 connected to a current source 54 via a switch 56.

As thus far described, the device is a controlled NOT (CNOT) gate and can be used in quantum or nanostructure binary computer installations as such. Lack of a bias, or a low level bias, at the tunnel region 36, represented by an open switch condition of switch 48 or 56, can be considered, for example, a “0” input. Electron density will appear at the output side of the input waveguide 26 (a “1” or “high” output). At the output side of the output waveguide 32 no electron density will appear (a “0” or “low” output). Application of a bias by closure of switch 48 or switch 52 may be considered an input “1.” The output side of the output waveguide 32 now is coupled via the tunnel region 36 to the input side of the input waveguide 26. Electron density is removed from the output side of the input waveguide (“0” or “low”) and appears at the output side of the output waveguide (“1” or “high”). A first controlled computational basis has thus been provided.

At the input side of the input waveguide 26 of the device 20 in FIG. 1, there is provided a quantum point contact (QPC) 60. A magnetic field source 64, schematically shown as a coil, is connected via a switch 66 with a current source 68.

In this instance device 20 is preferably an InGaAs/InAs heterostructure. InAs is used as the semiconductor of choice due to the enhanced Landé g-factor that InAs possesses, −15, as compared with more popular semiconductors such as GaAs, which has a g-factor of only −0.44. This allows filtering the electron spins with a reduced magnetic field.

In the absence of a magnetic field, the electron density introduced by the electron current source 40 will be without spin polarization. Upon application of the magnetic field the electrons at the quantum point contact will be polarized with either an up spin or a down spin depending on the direction (sign) of the magnetic field applied. This, then, gives a second, controlled, computation basis, i.e. spin-polarized electron density appearing at the output side of the device 20 or electron density without spin polarization appearing at the output side of the device. The two bases for computation-spin polarization or not and electron appearance in one or the other of the waveguides—are nonorthogonal computational bases. In known fashion, then, encryption of communications can be accomplished between the input side and the output side of the device 20, including the secure determination of encryption keys usable for encryption by the sender, who controls the spin and output coupling, and also usable for decryption by the receiver.

Although, in FIGS. 1-3, the device 20 has been represented as a stand-alone device for purposes of explanation, it will be understood that such devices can be part of an integrated circuit formed on a single chip. Also the use of individual voltage sources and current sources in FIG. 1 is for purposes of explanation only. Typically bias voltages and current available in an integrated circuit are available for use in known fashion to afford the needed potentials and electrical current. Magnetic field generation has been illustrated as being through the use of a coil whereas in integrated circuitry a single wire or deposited lead may be used in proximity to the device 20 to provide the desired magnetic field for spin polarization and for magnetic bias across the device in the tunnel region.

In FIG. 3, to stimulate more realistically the potential profile for the barrier potentials, at the metallic barrier members 28 and 30, the initial “hardwall” potential has been smoothed with a Gaussian distribution. The potential barrier, however, is still sufficiently high to prevent any leakage from the input waveguide to the output waveguide and to assure that all transfer of electron density from the input to the output occurs in the tunnel region 36.

The wider output region 33 of the output waveguide 32 assures that modes propagate through the coupling region and do not decay. The substrate of the device is doped to set the Fermi level. The Fermi energy in the structure is chosen to be 2 meV, which corresponds to a carrier density of 5.6×10¹⁰ cm⁻². This Fermi energy is chosen so that only one mode is excited in the input waveguide of the structure. Since the input waveguide structure is wider than the output waveguide structure at the input thereof, the mode that is excited at this energy will only propagate in the wider input waveguide. The particular dimensions of the waveguide structure can be easily scaled as long as the constraints mentioned are honored.

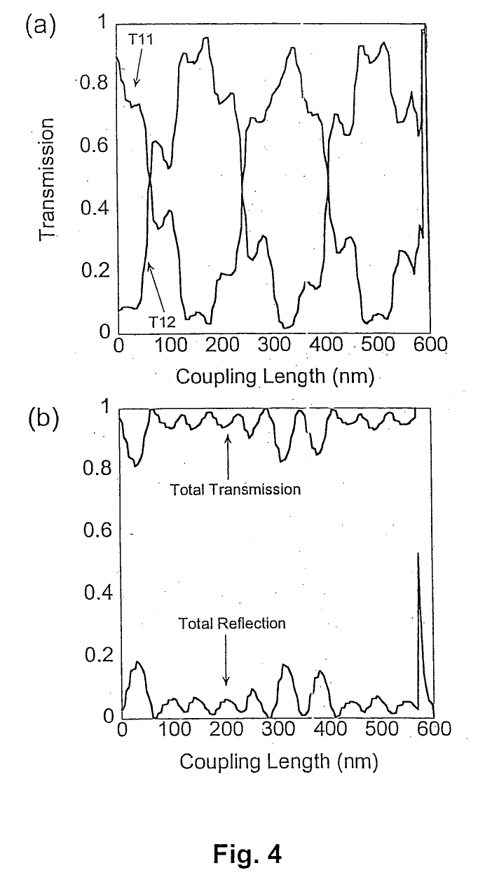

The density in the structure for varying coupling lengths is calculated to find the maximum output, which occurs at the peak in the coupling of the wavefunction from the input waveguide to the output waveguide. The results of a simulation are shown in FIG. 4. In FIG. 4(a) there are periodic fluctuations in transmission from the input waveguide to the output of the second waveguide 32 (such transmissions are designated here as T12), and from the input waveguide 26 to the output of the initial waveguide 26 (such transmissions are, here, T11). These fluctuations are periodic in coupling length at approximately 300 nm. Every 150 nm is an almost “pure” state (|0> or |1>). Other coupling lengths are at intermediate locations on the Bloch sphere and thus one finds superposition states. For the device of FIGS. 1-3, a coupling length of about 335 nm results in a maximum T11=0.90626 and a minimum T12=0.0303 resulting in an almost pure state. FIG. 4(b) plots the total transmission and total reflection against the coupling length. There remains a reflected component of 0.0671 at the optimum coupling length which accounts for the remainder of the density.

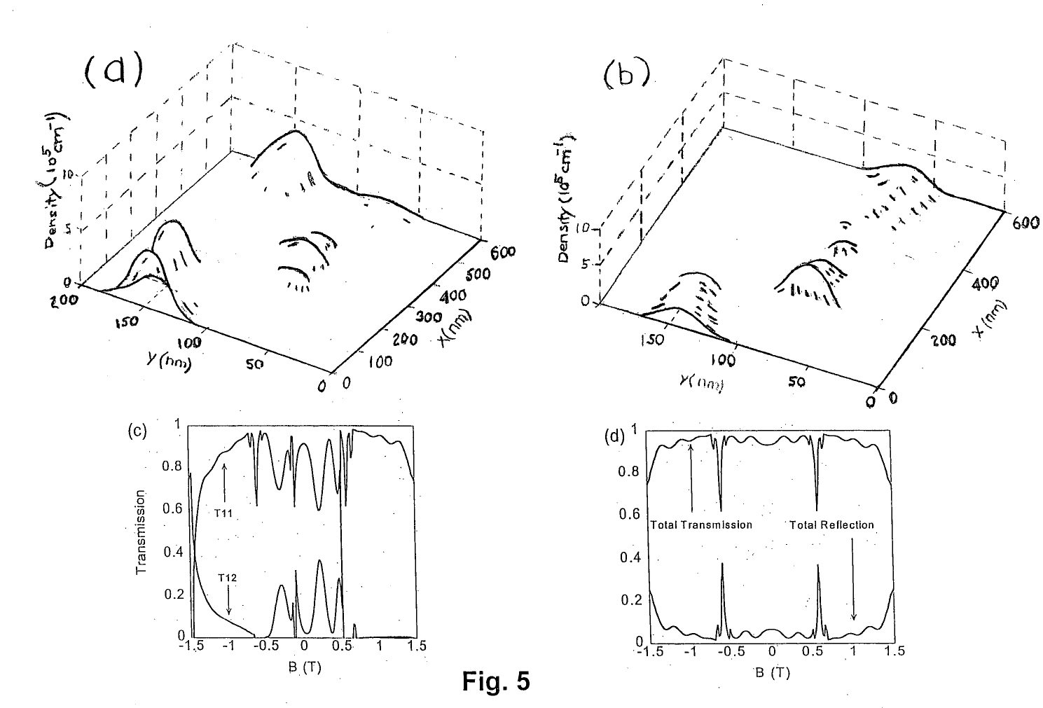

With a coupling length selected, various magnetic fields are applied and the resulting densities in the input waveguide 26 and the output waveguide 32 are plotted in FIG. 5. FIG. 5(a) plots the density with no magnetic field. As before, the majority of the density remains in the input waveguide 26 output or “cathode” section, maximizing transmission T11. As seen in FIG. 5(b), with a magnetic field of 0.705 T, the wavefunction is transferred from the input waveguide 26 input side (or anode) to the output waveguide 32 output side (or cathode) via the tunnel region 36 and a “pure” inverted state in the system is achieved, maximizing T12. From FIG. 5(c), T12 is approximately 0.983, T11 is approximately 3.451×10⁻⁵, and the total reflection is approximately 0.0171. While T11 is greater than zero, the value of this transmission is negligible compared to T12, which can be regarded as a “pure” state. Furthermore, from FIG. 3(d) it can be observed that the application of a magnetic field is a symmetric process in total transmission and reflection, but is not for the individual transmissions of the input and output waveguides (T11 and T12) individually. Minima of transmission occur at half-integer multiples of the cyclotron radii compared to the corresponding coupling length of the structure. Based on these results, it is determined that using this coupled waveguide structure a small magnetic field of 0.705 T will switch the outputs represented by the two waveguide output sides from a “low” to a “high” or “high” to “low” state.

While it is clear that the output of the coupled waveguide structure may be switched using a magnetic field, it is not clear that the application of a magnetic field is always the most efficient way to switch a quantum gate or qubit. In one exemplary embodiment the application of the magnetic field comes from the bias of a very thin wire affixed to the surface of the semiconductor. While the application of a magnetic field through the use of a small wire may be acceptable in the case of a single gate, magnetic switching may not be feasible in the case of a multiple gate structure. With the gate structures packed very tightly in the semiconductor structure, conceivably, many wires could be needed to switch the various individual gates. While it is possible to pack the gates tightly, it may very well not be possible to adequately control the current in the wires needed to switch the states of the individual gates. When the wires are brought into close proximity of each other, the magnetic fields of the individual wires will likely interfere and the result would be a shift in the magnitude of the magnetic field that the gates would see. This could result in an ineffective switching of the state of the gate. The effect is illustrated in FIG. 5(c), where the plateau is not terribly stable as small changes in the magnitude of the magnetic field produce a superposition state.

Therefore, in certain embodiments it is preferable to seek a means by which the state of the gate may be changed through the application of an applied electrical bias. This case is considered to be better where multiple gates are densely packed as the electrical bias may be applied in a much more localized fashion than the magnetic field.

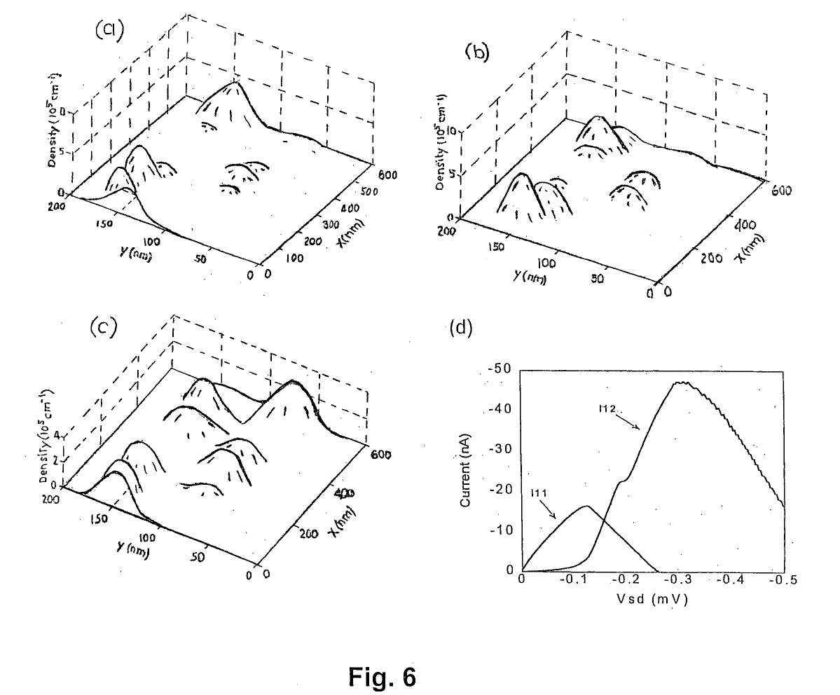

FIG. 6 plots the results of adding a voltage drop, ranging from 0 to −1.25 mV across the coupled waveguide structure of device 20. This adds an extra degree of freedom to the carriers in the system, and it is no longer viable to discuss the operation of the device in terms of just the transmissions and reflections of incident modes. The addition of an extra degree of freedom to the carriers excites extra output modes which are indistinguishable in the total transmission from the initially excited mode (determined by the setting of the Fermi energy). Therefore, in order to determine the extent to which this device switches from one pure state to the next, the Landauer formula is used to integrate over the individual transmissions and compute the current. FIG. 6(a) shows the density plotted with no applied bias at the T11 maximum. As expected, the plot is identical to FIG. 5(a). A negative bias is now applied (applied uniformly from the source at the left end to the drain at the right end) across the device. The resulting density change is shown in FIGS. 6(b) and 6(c) for applied biases of −0.243 mV and −0.318 mV respectively. While it is clear from FIGS.6(b) and 6(c) that the majority of the density has switched and is now propagating at the output waveguide 32 output end (cathode), the current flowing in each waveguide 26 and 32 must be looked at to determine the level of success in switching of the waveguide states. In FIG. 6(d), in the case of both the −0.243 mV and −0.318 mV applied biases, no current is flowing in the input waveguide output or cathode (I11) and a vast majority of the current flowing is in the output waveguide 32 output or cathode (I12), thereby giving a switched state. The magnitudes of the currents flowing at these applied biases are −46 nA at −0.243 mV applied bias and −40 nA at −0.318 mV. Further, in both cases the total current, and the current that is flowing at the input or anode end of the output waveguide 32, are equal. Thus, the switching from one pure state to another is complete as the applied bias is increased. Moreover, in FIG. 6(d) the current in the device pinches off at −0.6 mV. This is expected, as when the applied negative bias increases, the Fermi level at the input or anode end of the structure eventually drops below a point in energy where propagating modes can be supported in the structure. Therefore, the device pinches off.

A simulation of this system has performed on a discretized grid using a variation of the Usuki mode matching technique via the scattering matrix, using a grid spacing of 5 nm. The simulation of the system was kept as realistic as possible. To this end, thermal effects and Zeeman splitting into the system were included.

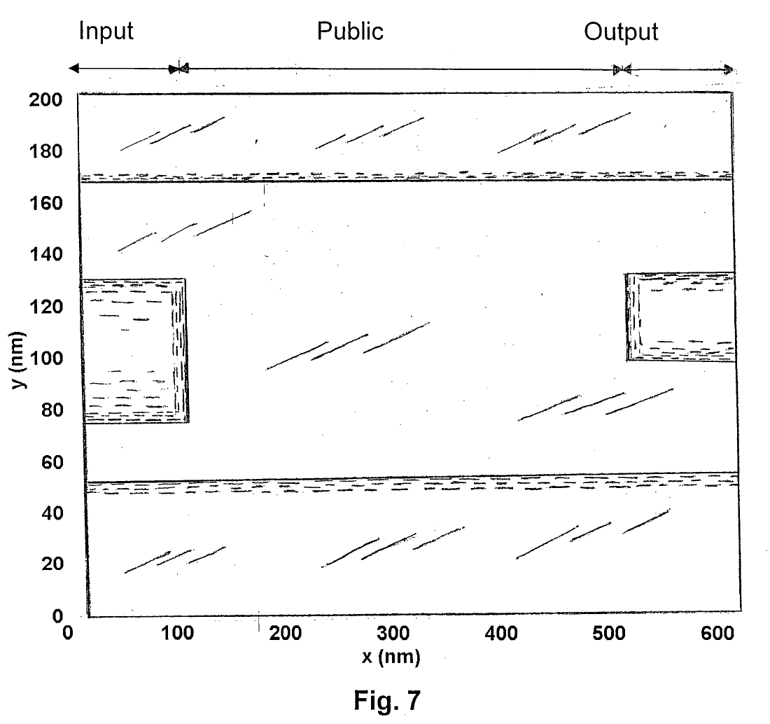

FIG. 7 is a two dimensional profile of the structure used in a simulation of the device of the invention. In this figure, the corresponding operational sections of the system are labeled. The first section is the input section which contains the quantum point contact (QPC) and extends to the end of the potential barrier. It is here that the incoming mode is polarized (or not) by the local magnetic field in the QPC. Further, the public section contains the tunnel region. In this section, the mode interacts with the output waveguide and, based on an input electrical bias, selects an output waveguide. Finally, the output region is shown where the receiver makes measurements.

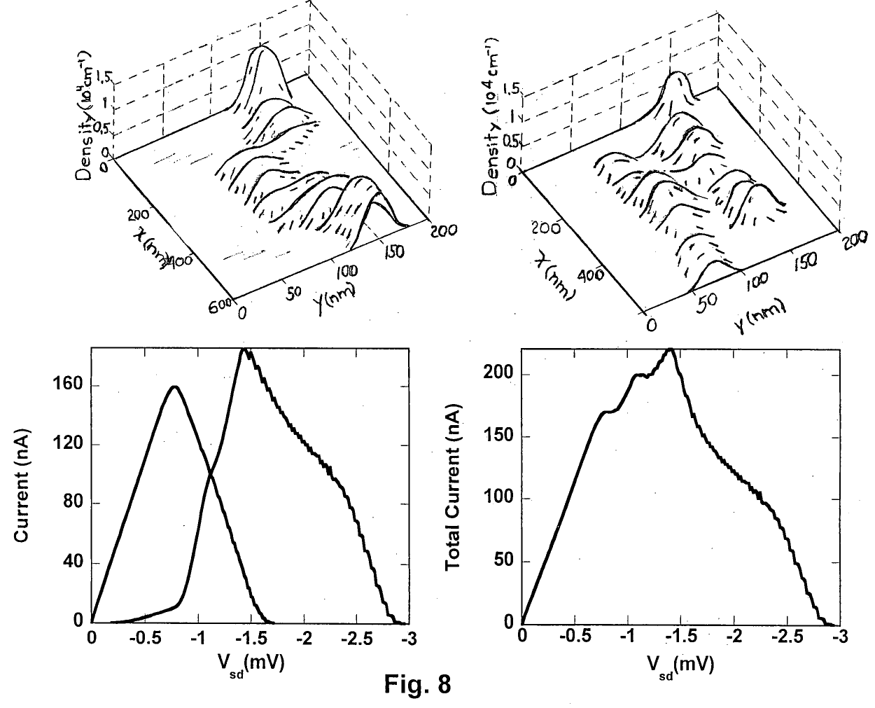

The effects of electrical bias are illustrated in FIG. 8. In FIG. 8(a) is shown electron density when the electrical bias is V_{sd}=−0.78 mV with T=0.7 K. This corresponds to a maximal current in the transmitted current present in the input waveguide (|11). In FIG. 8(b), electron density is shown when the electrical bias is V_{sd}=−1.64 mV with T=0.7 K. This corresponds to a maximal current in the output waveguide (|12). FIG. 8(c) plots |11 and |12 against a varying electrical bias to show the profile of the individual transmissions. In FIG. 8(d), total current flowing in the device is plotted against a varying electrical bias to show the profile of the total transmission through the device.

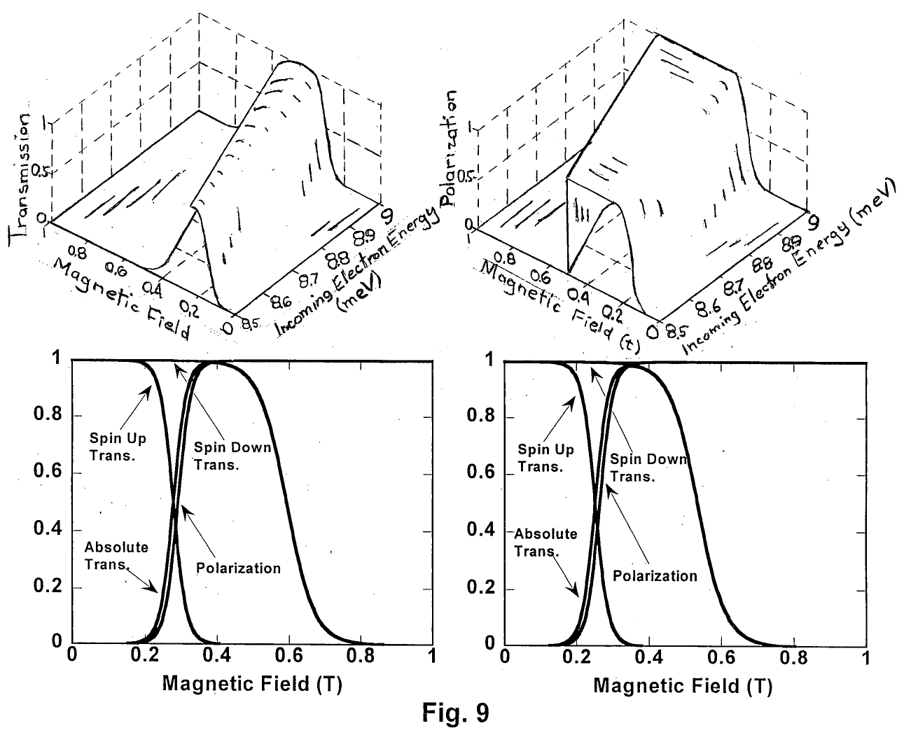

FIG. 9 illustrates the operation of the quantum point contact as a spin filter. FIG. 9(a) is a surface plot of the absolute transmission probability (T_{abs}=T↓−T↑) for a QPC of potential profile V(x, y)=V₀−½m·ωₓ²x²+½m·ω_{y}²y² with V₀=8.0 meV, [symbol] ωₓ=0.1 meV, [symbol] ω_{y}=0.05 meV, and T=0.7 K with varying energy and magnetic field. FIG. 9(b) is a surface plot of the polarization

$$( P = \frac{T ↓ - T ↑}{T ↓ + T ↑} )$$

of the incoming electrons plotted against varying energy and magnetic field. FIG. 9(c) plots filtration characteristics for electrons with incident energy corresponding to V_{sd}=−0.78 mV. And FIG. 9(d) plots filtration characteristics for electrons with incident energy corresponding to V_{sd}=−1.64 mV.

FIG. 9 illustrated simulated operation of the cryptographical device 20. FIG. 9(a) plots the random variable a which controls the ultimate location of the electron density as a function of time. FIG. 9(b) plots the random variable b which controls the polarization of the electron density as a function of time. FIG. 9(c) plots the current flowing in the input waveguide at the receiver end of the device as a function of time. In the simulation, we have assumed that both the applied bias and the magnetic field may be switched on a time scale of picoseconds. Further, we also assume that using a hold time of 3 ns gives enough time for the mode to propagate from the sender to the receiver. We can see that the spin polarized current values do not differ much from the non-polarized values, thereby giving an eavesdropper very little additional information as to the value of b. FIG. 9(d) plots the current flowing in the output waveguide at the receiver end of the device as a function of time. While at the I11 maximum the current in the output waveguide does not vanish, the transmission probabilities and, therefore, the current is greatly reduced. While it is ideal for I12 to disappear at the I11 maximum, the device operation, due to the definition of the protocol, is not affected.

The encrypting protocol chosen is a variation of the B92 protocol of C. H. Bennett, cited above. It operates in the following manner. The sender randomly chooses numbers a and b where a corresponds to the location of the density, ‘0’ or ‘1’, and b corresponds to the polarization of the propagating density, ‘0’ or ‘1’. Thus, as the electron density passes the input end of the device into the tunnel region, there are four possible states for the electrons:

$$ψ = \frac{\vert 0 ↑ ⟩ + \vert 0 ↓ ⟩}{\sqrt{2}} ( a = 0 , b = 0 ) , \vert 0 ↓ ⟩ ( a = 0 , b = 1 ) , \frac{\vert 1 ↑ ⟩ + \vert 1 ↓ ⟩}{\sqrt{2}} ( a = 1 , b = 0 ) , or \vert 1 ↓ ⟩ ( a = 1 , b = 1 ) .$$

The receiver then chooses a measurement basis and records the outcome of his or her measurement, his or her measurement basis, and the waveguide in which the electron density arrived. The measurement basis and the waveguide in which the electron density arrived are then publicly communicated to the sender from the receiver to reconcile and throw away incorrect measurements on the arriving density. With a protocol in place, the system is broken up into three operational areas to explain the operation of the device. These are input region, public region, and output region as shown in FIG. 7.

The input end of the device is defined as the section of the system that is to the left of the start of the coupling tunnel region 36 in FIGS. 1-3. It is assumed that the mode that is propagating at the input end of the device consists of mixed spins, or

$$ψ = \frac{\vert α ↑ ⟩ + \vert β ↓ ⟩}{\sqrt{2}}$$

where α and β are real numbers. For a message to be sent, the sender varies the electrical or magnetic bias applied to the system at 42, 44 or 52 and the magnetic field applied to the QPC 60. The applied bias is used to control in which waveguide 26 or 32 the electron density arrives at the output end of the device and ultimately determines the value of a. Lower biases are used to send the electron density to the output of the input waveguide 26 (a=0) and higher biases are used to send the electron density to the output of the output waveguide 32 (a=1). This varying of the position of the electron density provides the sender with one basis upon which he or she may send his or her bits. To have a cryptographical key, at least two nonorthogonal bases must be present in the system. As described previously the QPC 60 with a magnetic field applied at 64 to polarize the electron spins of the incoming mode that ultimately determines the value of b which is the second nonorthogonal basis available to the sender. A high value of magnetic field will polarize the density when a=0 and a low magnetic field polarizes the density when a=1.

At the input end of the device, the sender controls the operation of the QPC 60 and the electrical or magnetic bias that is applied to the system and the values of these are known only by the sender. Therefore, at the input end the sender may choose to send any of the four states based on the values of the applied bias as illustrated in FIG. 8 and the local magnetic field in the QPC as illustrated in FIG. 9.

As the mode passes through the QPC 60 and assumes one of the four possible states, it enters the public region of the device, which consists of the 335 nm coupling region 36 between the input and output waveguides 26 and 32. In this region, the system is open to eavesdropping from third parties. Nevertheless, this is a rather futile task in that not only must the third party choose one of the four possible bases in which to measure the transmitted bit, but while the electron density interacts with the output waveguide it has not yet revealed its final destination of the input or the output waveguide thereby yielding the eavesdropper no insight as to which basis to choose. This makes the deciphering of the key extremely difficult as the probability of choosing the correct basis is remote. Further, the detection of the eavesdropper is quite simple as the measurement made in the public section of the system, no matter how non-intrusive, will corrupt the transmission coefficients by forcing the wavefunction into a state that does not correspond to the intended state resulting in bit transmission errors detectable by the receiver.

With the mode passing the public area of the system, it enters the output end of the device. The output end of the device consists of the 35 nm input and 45 nm section of output waveguides 26 and 32. As the electron density arrives in either the input or the output waveguide with its given spin polarization, the receiver chooses a value for a by measuring either the input or output waveguide. At the same time, the receiver must also set up the measurement instrumentation to measure either the mixed electron spin of the nonpolarized basis or the spin polarized basis to determine the value of b from the eigenstate of the measurement basis. It should be noted that in the output region, we do not need to assume that we are free from eavesdropping. This is true because the wavefunction is still in one of the four possible states as in the public section of the device. Therefore, the chances of the key being deciphered are still quite low. Once the basis has been chosen and the current is measured, the receiver records the waveguide in which the electron density has arrived, the basis in which the measurement has been made, and the result of the measurement. Information is publicly reconciled and thus, at the end of the reconciliation, the sender and the receiver have the same bit set and the message has been successfully transmitted. If, however, eavesdropping has occurred in either the public or the output region, then discrepancies will show up in the bits measured with the bits sent and the message must be resent.

Although preferred embodiments of the invention have been described in detail, it will be readily appreciated by those skilled in the art that further modifications, alterations and additions to the invention embodiments disclosed may be made without departure from the spirit and scope of the invention as set forth in the appended claims.

We claim:

1. A quantum gate comprising two waveguides, an input section of at least one of the waveguides leading to a coupling region where the two waveguides are coupled, an output section of each of the waveguides leading from the coupling region to an output end of the waveguide, and at least one bias element operative to apply one of an electrical and magnetic bias to the gate to cause carriers moving through the input section of the at least one waveguide into the coupling region to be coupled to one or the other of the output sections of the waveguides in dependence on application of the bias.

2. The quantum gate of claim 1, wherein the coupling region is a tunneling region for passing carriers from the at least one waveguide to the other waveguide by tunneling.

3. The quantum gate of either claim 1 or 2, wherein the at least one bias element is operative to apply an electrical bias across the gate to force carrier movement across the coupling region from the input section of the at least one waveguide to one or the other of the output sections.

4. The quantum gate of either claim 1 or 2, wherein the at least one bias element is operative to apply a magnetic bias to the gate to force carrier movement across the coupling region from the input of the at least one waveguide to one or the other of the output sections.

5. The quantum gate of claim 4, wherein the bias element is a conductor proximate the coupling region.

6. The quantum gate of either claim 1 or 2, wherein the waveguides and the coupling region are a part of a semiconductor structure.

7. The quantum gate of claim 6, the semiconductor structure being of a InAs/InGaAs heterostructure.

8. The quantum gate of either claim 1 or 2, wherein the at least one waveguide is of substantially uniform width and the other waveguide has an output region that is wider than the width of the at least one waveguide.

9. The quantum gate of claim 8, wherein the other waveguide has an input region leading to the coupling region that is narrower than the output region of that waveguide.

10. The quantum gate of either claim 1 or 2, wherein the coupling region is 300 to 450 nm in length.

11. The quantum gate of claim 10, wherein the waveguides are 20 to 50 nm in width.

12. The quantum gate of either claim 1 or 2, wherein the waveguides are separated by a potential barrier at locations other than the coupling region.

13. The quantum gate of claim 9, wherein the input and output regions of the waveguides are separated by a potential barrier.

14. The quantum gate of claim 12, wherein the potential barriers comprise deposited conductors.

15. The quantum gate of claim 12, further comprising potential barriers defining edges of the waveguides spaced from the potential barriers separating the waveguides.

16. The quantum gate of claim 15, wherein the potential barriers comprise deposited conductors.

17. The quantum gate of 13, further comprising potential barriers defining edges of the waveguides spaced from the potential barriers separating the waveguides.

18. The quantum gate of claim 17, wherein the potential barriers comprise deposited conductors.

19. The quantum gate of either claim 1 or 2, further comprising means associated with the input region of the at least one waveguide operative to modify a quantum characteristic of charge carriers moving in that input region towards the coupling region.

20. The quantum gate of claim 19, wherein the quantum characteristic is electron spin, whereby carriers moving in the input region of the at least waveguide are selectively electron spin polarized by operation of the means to modify a quantum characteristic.

21. The quantum gate of claim 19, wherein the quantum characteristic is electron spin and wherein the means to modify a quantum characteristic is a quantum point contact (QPC) and a source of magnetic field associated with the input region of the at least one waveguide.

22. The quantum gate of either claim 1 or 2, further comprising a quantum point contact and a source of magnetic field associated with the input region of the at least one waveguide operative selectively to effect electron spin polarization of carriers moving in that input region.

23. The quantum gate of either claim 1 or 2, wherein the charge carriers are electrons.

24. The quantum gate of either claim 1 or 2, wherein the waveguides are defined by deposited metal conductors operative to develop potential barriers in a semiconductor substrate on which they are deposited and in which the charge carriers move.

25. A semiconductor gate device comprising:
(a) a first means for communicating a number of charge carriers from a first location to a second location,
(b) a second means for communicating a number of charge carriers to the second location,
(c) means located intermediate first and second ends of the first means for communicating for coupling the first means for communicating to the second means for communicating, and
(d) means for applying at least one of a magnetic and an electrical bias to charge carriers moving in the first means for communicating to determine to which of the first and the second means for communicating the charge carriers move via the coupling means.

26. The gate device of claim 25, wherein the first location is a first end of the device where the charge carriers are introduced into the first means for communicating, and the second location is a second end of the device to which the charge carriers move.

27. The gate device of claim 26, wherein the first and second communicating means are first and second waveguides, respectively.

28. The gate device of claim 27, wherein the means for coupling is a tunneling region.

29. The gate device of claim 28, wherein the means for applying at least one of a magnetic and an electrical bias comprises means for applying a magnetic bias across the device to influence which of the first and second waveguides delivers the charge carriers to the second end of the device.

30. The gate device of claim 28, wherein the means for applying at least one of a magnetic and an electrical bias comprises a means for applying an electrical bias across the device to influence which of the first and second waveguides delivers the charge carriers to the second end of the device.

31. The gate device of claim 25, further comprising means for influencing a quantum state of the charge carriers.

32. The gate device of claim 31, wherein the means for influencing a quantum state of the charge carriers comprises means for effecting electron spin polarization.

33. The gate device of claim 32, wherein the means for effecting spin polarization comprises a quantum point contact and means for applying an magnetic field at the quantum point contact.

34. The gate device of claim 33, wherein the quantum point contact is imbedded in the first means for communicating at a location between the first location and the means for coupling.

35. A semiconductor waveguide gate device comprising:
(a) a first waveguide boundary,
(b) a second waveguide boundary spaced from and substantially parallel to the first waveguide boundary,
(c) a first metallic member defining a first waveguide separating boundary protruding between the first waveguide boundary and the second waveguide boundary,
(d) a second metallic member defining a second waveguide separating boundary protruding towards the first electrode between the first waveguide boundary and the second waveguide boundary,
(e) each of the first and second metallic members having edges facing the first waveguide boundary to define a potential barrier spaced substantially the same distance a from the first waveguide boundary,
(f) each of the first and second metallic members having a further edge facing the second waveguide boundary,
(i) the further edge of the first metallic member being spaced from the second waveguide boundary to produce a potential barrier a distance b from the second waveguide boundary,
(ii) the further edge of the second metallic member being spaced from the second waveguide to produce a potential barrier a distance c from the second waveguide boundary that is greater than a,
(iii) the further potential barriers of the first and second metallic members forming with the second waveguide boundary a second waveguide along the second waveguide boundary,
(g) the first and second metallic members having ends separated by a coupling, and
(h) bias applying means located to selectively apply one of a magnetic and an electrical bias to charged particles moving in the first and second waveguides.

36. A semiconductor quantum cryptography system comprising two parallel waveguides, separated by an electrostatic potential barrier and coupled via a tunnel region, a top one of the two waveguides having a uniform width of substantially 35 nm with a small quantum point contact (QPC) with a width of about 35 nm and a length of about 20 nm embedded in an input side of an input waveguide, a further one of the two waveguides being narrowed at its source end to substantially 25 nm and widened to a width of substantially 45 nm on an output side of the tunnel region, and means for controlling spin of the electron, either up or down depending on the sign of an applied filtering magnetic field, and to form with the location of the electron density two non-orthogonal bases for encryption of bits.

37. The semiconductor quantum cryptography system according to claim 36, wherein the electrostatic potential barrier that separates the input and output waveguides begins with a width of substantially 50 nm and then narrows to substantially 25 nm on the output side of the tunnel region.

38. The semiconductor quantum cryptography system according to claim 37, further comprising doping to set a Fermi level that corresponds to a Fermi energy where one mode propagates in the input waveguide.

39. A method of transistor quantum gate operation comprising:
(a) providing in a semiconductor substrate a first waveguide,
(b) providing in the semiconductor substrate a second waveguide,
(c) providing a coupling between the first and the second waveguide,
(d) moving a charge carrier current in one of the waveguides, and
(e) selectively controlling the path of electron current to one or the other of outputs of the waveguides by applying at least one of an electrical and a magnetic bias to the electron current to cause tunneling of the current in the coupling.

40. The method of transistor quantum gate operation according to claim 39, wherein steps (a) and (b) comprise developing barrier potentials in the substrate to define the waveguides.

41. The method of transistor quantum gate operation according to claim 40, wherein developing the barrier potentials comprises:
(i) developing a first barrier potential separating the waveguides at their input ends between inputs to the waveguides and the coupling, and
(ii) developing a second barrier potential separating the waveguides at their output ends between outputs from the waveguides and the coupling.

42. The method of transistor quantum gate operation according to claim 41, wherein developing the first and second barrier potentials comprises defining one waveguide that is wider at its output end than width of the other waveguide at its input end.

43. The method of transistor quantum gate operation according to claim 39, further comprising selectively polarizing the electron spin of charge carriers moved in one of the waveguides.

44. A method of encryption between a sender and a receiver in a solid state device comprising the sender randomly choosing numbers a and b where a corresponds to a location of an electron density, ‘0’ or ‘1’, and b corresponds to a polarization of the propagating density as it passes through a tuned quantum point contact, ‘0’ or ‘1’, as the electron density passing the electron density through an input end of the device into a tunnel region of the device in one of four possible states for the electrons:
$$ψ = \frac{\vert 0 ↑ ⟩ + \vert 0 ↓ ⟩}{\sqrt{2}} ( a = 0 , b = 0 ) , \vert 0 ↓ ⟩ ( a = 0 , b = 1 ) ,$$
$$\frac{\vert 1 ↑ ⟩ + \vert 1 ↓ ⟩}{\sqrt{2}} ( a = 1 , b = 0 ) , or \vert 1 ↓ ⟩ ( a = 1 , b = 1 ) ,$$
the receiver choosing a measurement basis and recording the outcome of the receiver's measurement, the receiver's measurement basis, and which of plural waveguides the electron density arrived on, publicly communicating to the sender from the receiver the measurement basis and the waveguide in which the electron density arrived to reconcile and throw away incorrect measurements on the arriving density.

45. The method of encryption according to claim 44, further comprising using one of the spin down state of the electron by applying a negative magnetic field to the electron density as it passes through the quantum point contact, or using the spin up state of the electron by applying a positive magnetic field to the electron density as it passes through the quantum point contact.

46. A method of secure, encrypted communication comprising:
(a) providing a movement of a series of charge carrier densities,
(b) selectively electron spin polarizing some of the charge carrier densities in the series in one spin direction, while not electron spin polarizing in that spin direction the remaining charge carrier densities in the series,
(c) irrespective of electron spin polarization, directing the movement of a portion of the charge carrier densities along a first path, and
(d) irrespective of electron spin polarization, directing movement of a remaining portion of the charge carrier densities along a second path.

47. The method of secure, encrypted communication of claim 46, wherein step (b) comprises leaving the remaining charge carrier densities without electron spin polarization.

48. The method of secure, encrypted communication of claim 46, wherein step (b) comprises providing a quantum point contact and applying a magnetic field at the quantum point contact to those charge carrier densities to be electron spin polarized.

49. The method of secure, encrypted communication of any one of claims 46, 47 or 48, wherein step (c) comprises:
(i) providing a first waveguide, and
(ii) directing the portion of the charge carrier densities along the first waveguide to a first output, and
step (d) comprises:
(i) providing a second waveguide, and
(ii) directing the remaining portion of the charge carrier densities along the second waveguide to a second output.

50. The method of secure, encrypted communication of claim 49, further comprising providing a coupling between the waveguides, and wherein directing the remaining portion of the charge carrier densities along the second waveguide comprises directing the remaining portion from a part of the first waveguide to the second waveguide via the coupling.

51. The method of secure, encrypted communication of claim 50, wherein directing the remaining portion of the charge carrier densities from a part of the first waveguide to the second waveguide comprises applying at least one of an electric and a magnetic bias to the remaining portion.

52. The method of secure, encrypted communication of claim 51, wherein the steps of providing a first waveguide and providing a second waveguide comprises defining the first and the second waveguide in a semiconductor by establishing electrical potentials defining the waveguides, and the step of directing the remaining portion of the charge carrier densities from a portion of the first waveguide to the second waveguide via the coupling comprises providing a tunnel region coupling the waveguides and selectively applying the bias to choose which of the charge carrier densities to direct to the second waveguide via the tunnel region.

53. The method of secure, encrypted communication of claim 46, wherein four output characteristics are produced of the form:
$$ψ = \frac{\vert 0 ↑ ⟩ + \vert 0 ↓ ⟩}{\sqrt{2}} ( a = 0 , b = 0 ) , \vert 0 ↓ ⟩ ( a = 0 , b = 1 ) ,$$
$$\frac{\vert 1 ↑ ⟩ + \vert 1 ↓ ⟩}{\sqrt{2}} ( a = 1 , b = 0 ) , or \vert 1 ↓ ⟩ ( a = 1 , b = 1 ) ,$$
where a and b are the first and second outputs.
